(19) United States
(12) Patent Application Publication
(10) Pub. No.: US 2025/0333348 A1
(43) Pub. Date: Oct. 30, 2025

(54) GLASS FIBER PRODUCT, PREPREG AND COPPER CLAD LAMINATE

(71) Applicant: FULLTECH FIBER GLASS CORP., Douliu City (TW)

(72) Inventors: Kuo-Hsin CHANG, Douliu City (TW); Ming-Feng CHENG, Douliu City (TW); Bih-Cherng CHERN, Douliu City (TW); Jian-Ting LEE, Douliu City (TW); Hui-Ru SHEN, Douliu City (TW); Hsiu-Hung LEE, Douliu City (TW)

(21) Appl. No.: 19/185,993

(22) Filed: Apr. 22, 2025

(30) Foreign Application Priority Data
Apr. 25, 2024 (TW) 113115378

(51) Int. Cl. C03C 13/00; B32B 5/02; B32B 15/14; B32B 15/20; C03C 3/118; C08J 5/24; H05K 1/03

(52) U.S. Cl. CPC C03C 13/00; B32B 5/024; B32B 15/14; B32B 15/20; C03C 3/118; C08J 5/248; H05K 1/0366; B32B 2260/021; B32B 2260/046; B32B 2262/101; B32B 2307/30; B32B 2311/12; B32B 2457/08; C08J 2363/00; C08J 2371/12; C08J 2379/08

(57) ABSTRACT

A glass fiber product includes a glass fiber fabric and a silane coupling agent. The glass fiber fabric has glass fiber yarns woven together. Each of the glass fiber yarns is made of glass fibers and includes a glass composition. The glass composition has a coefficient of thermal expansion (CTE) ranging from 2 ppm/° C. to 3 ppm/° C., a dielectric constant (Dₖ) ranging from 4.0 to 5.0 at 10 GHZ, and a dielectric loss tangent (D_{f}) ranging from 0.0010 to 0.0040 at 10 GHz. The CTE, the Dₖ, and the D_{f} of the glass composition satisfy an equation of 1.0 ≤1000×(D_{f}/Dₖ)×(CTE)²≤7.2. A prepreg includes a resin material, an inorganic filler, and the glass fiber product. A copper clad laminate includes the prepreg.

### CROSS-REFERENCE TO RELATED APPLICATION

This application claims priority to Taiwanese Invention patent application Ser. No. 11/311,5378, filed on Apr. 25, 2024, the entire disclosure of which is incorporated by reference herein.

### FIELD

The disclosure relates to a glass fiber product, and a prepreg having the same. This disclosure also relates to a copper clad laminate including the prepreg.

### BACKGROUND

With development of current 5G wireless transmission technology and chips for fast computing, the demand for functionality of circuit board in many high-end electronic devices has also increased. For example, the dimension change of the circuit board, after being heated, should not be too large. In addition, the circuit board should possess the advantages of fast computing and signal transmission. In order to reduce the dimension change of the circuit board after heating, materials with a low coefficient of thermal expansion (CTE) should be selected. In order to enable the circuit board to support fast computing and signal transmission, materials with a low dielectric constant (Dₖ) and a low dielectric loss tangent (D_{f}) should be selected.

At present, common glass fiber products for preparing the circuit boards in the market include T-glass fiber products, E-glass fiber products, NE-glass fiber products, etc. Among them, while the T-glass fiber products have a CTE not greater than 3 ppm/° C., the T-glass fiber products, at 10 GHZ, exhibit a Dₖ greater than 5.0 and a D_{f} greater than 0.0065. As such, the T-glass fiber products are not suitable to be used as circuit boards capable of fast computing and signal transmission. The E-glass fiber products have a CTE greater than 5 ppm/° C., a Dₖ greater than 6.0 at 10 GHZ, and a D_{f} greater than 0.0060 at 10GHz, and thus the E-glass fiber products are not suitable for the circuit boards required in the 5G wireless transmission technology. Although the NE-glass fiber products, at 10 GHZ, have a Dₖ not greater than 5.0 and a D_{f} not greater than 0.0035, a CTE thereof is greater than 3 ppm/° C., making the NE-glass fiber products unsuitable for use as circuit boards with minimal dimensional change after being heated.

Based on the above, in order to promote the technological development of massive 5G wireless transmission and fast computing with big data, providing a glass fiber product with a low CTE, a low Dₖ, and a low D_{f} is a common goal of the industry.

### SUMMARY

Therefore, an object of the disclosure is to provide a glass fiber product, a prepreg having the glass fiber product, and a copper clad laminate having the prepreg that can alleviate at least one of the drawbacks of the prior art.

According to a first aspect of the disclosure, a glass fiber product include a glass fiber fabric and a silane coupling agent. The glass fiber fabric has glass fiber yarns woven together. Each of the glass fibers is made of glass fibers and includes a glass composition. The glass composition has a coefficient of thermal expansion (CTE) ranging from 2 ppm/° C. to 3 ppm/° C., a dielectric constant (Dₖ) ranging from 4.0 to 5.0 at 10 GHZ, and a dielectric loss tangent (D_{f}) ranging from 0.0010 to 0.0040 at 10 GHz. The CTE, the Dₖ, and the D_{f} of the glass composition satisfy an equation of 1.0≤1000×(D_{f}/Dₖ)×(CTE)²≤7.2.

According to a second aspect of the disclosure, a prepreg includes a resin component, an inorganic filler, and the aforesaid glass fiber product.

According to a third aspect of the disclosure, a copper clad laminate includes the aforesaid prepreg.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

An embodiment of a glass fiber product according to the present disclosure includes a glass fiber fabric and a silane coupling agent. A surface-treated glass fiber fabric (i.e., the glass fiber product) may be obtained by subjecting the glass fiber fabric to a surface treatment with the silane coupling agent.

The glass fiber fabric has glass fiber yarns woven together. Each of the glass fiber yarns is made of glass fibers, and includes a glass composition. The glass composition has a coefficient of thermal expansion (CTE) ranging from 2 ppm/° C. to 3 ppm/° C., a dielectric constant (Dₖ) ranging from 4.0 to 5.0 at 10 GHZ, and a dielectric loss tangent (D_{f}) ranging from 0.0010 to 0.0040 at 10 GHz. The CTE, the Dₖ, and the D_{f} of the glass composition satisfy an equation of 1.0≤1000×(D_{f}/Dₖ)×(CTE)²≤7.2. Specifically, the glass fibers may be obtained by subjecting the glass composition to a melting treatment and a filament drawing process. The glass fiber yarns may be obtained by subjecting the glass fibers to a sizing treatment, a winding treatment, and a twisting treatment.

In some embodiments, the glass composition include silicon dioxide (SiO₂), aluminum oxide (Al₂O₃), calcium oxide (CaO), magnesium oxide (MgO), copper oxide (CuO), and boron oxide (B₂O₃). In some embodiments, silicon dioxide is in an amount ranging from 50 wt % to 60 wt % based on a total weight of the glass composition. In some embodiments, aluminum oxide is in an amount ranging from 15 wt % to 22 wt % based on the total weight of the glass composition. In some embodiments, calcium oxide is in an amount greater than 0 wt % and less than 6 wt % based on the total weight of the glass composition. In some embodiments, magnesium oxide is in an amount greater than 0 wt % and less than 7 wt % based on the total weight of the glass composition. In some embodiments, copper oxide is in an amount greater than 0 wt % and less than 2 wt % based on the total weight of the glass composition. In some embodiments, boron oxide is in an amount greater than 10 wt % and less than 20 wt % based on the total weight of the glass composition. When each of ingredients of the glass composition is controlled in the aforesaid ranges, the glass composition may exhibit the CTE ranging from 2 ppm/° C. to 3 ppm/° C., the Dₖ ranging from 4.0 to 5.0 at 10 GHZ, and the D_{f} ranging from 0.0010 to 0.0040 at 10 GHz.

In the present disclosure, by controlling the amount of silicon dioxide to range from 50 wt % to 60 wt %, a viscosity of the glass composition may be reduced, which is beneficial to perform the melting treatment. By controlling the amount of aluminum oxide to range from 15 wt % to 22 wt %, the viscosity of the glass composition may be reduced, which is beneficial to perform the melting treatment; and the glass composition may be less likely to crystallize during manufacturing processes for forming the glass fiber, which is beneficial to perform the filament drawing process. By controlling the amount of calcium oxide to be greater than 0 wt % and less than 6 wt %, the viscosity of the glass composition may be reduced, which is beneficial to perform the melting treatment; the glass composition may be less likely to crystallize during manufacturing processes for forming the glass fiber, which is beneficial to perform the filament drawing process; and the CTE of the glass composition may be reduced. By controlling the amount of magnesium oxide to be greater than 0 wt % and less than 7 wt %, the viscosity of the glass composition may be reduced, which is beneficial to perform the melting treatment; and compactness of the glass composition may be improved such that each of the glass composition and the glass fibers obtained therefrom may have a reduced CTE and a reduced Dk. By controlling the amount of copper oxide to be greater than 0 wt % and less than 2 wt %, the compactness of the glass composition may be improved such that each of the glass composition and the glass fibers obtained therefrom may have the reduced CTE; and the glass composition may be less likely to crystallize during manufacturing processes for forming the glass fiber, which is beneficial to perform the filament drawing process. By controlling the amount of boron oxide to be greater than 10 wt % and less than 20 wt %, the viscosity of the glass composition may be reduced, which is beneficial to perform the melting treatment; the glass composition may be less likely to crystallize during manufacturing processes for forming the glass fiber, which is beneficial to perform the filament drawing process; and the compactness of the glass composition may be improved so that each of the glass composition and the glass fibers obtained therefrom may have a reduced CTE, a reduced Dₖ, and a reduced D_{f}.

In some embodiments, the glass composition further includes zinc oxide such that the CTE of the glass composition and the CTE of the glass fibers obtained therefrom may be further reduced. In certain embodiments, based on a total weight of the glass composition, zinc oxide is in an amount greater than 0 wt % and less than 8 wt %.

In some embodiments, the glass composition further includes a fluorine-containing material (e.g., a fluorine-containing mineral) such that the viscosity of the glass composition may be further reduced, which is beneficial to perform the melting treatment. In addition, the Dₖ and the D_{f} of the glass composition may also be further reduced. In certain embodiments, the fluorine-containing material is in an amount greater than 0 wt % and not greater than 1 wt % based on the total weight of the glass composition.

In some embodiments, the glass composition further includes a doping component. The doping component includes a fluxing agent and an additive. The fluxing agent may be used to reduce a melting point of the glass composition, thereby facilitating melting of the glass composition at a relatively lower temperature to form the glass fibers. In some embodiments, the fluxing agent includes sodium oxide (Na₂O), potassium oxide (K₂O), or a combination thereof. In some embodiments, the additive includes a metal. Example of the metal includes iron oxide (Fe₂O₃), but is not limited thereto. In some embodiments, the doping component is selected from the group consisting of sodium oxide, potassium oxide, iron oxide, and combinations thereof. In certain embodiments, based on the total weight of the glass composition, the doping component is in an amount greater than 0 wt % and not greater than 1 wt %.

The silane coupling agent may be used in the surface treatment for treating the glass fiber fabric so as to facilitate an interaction between the surface-treated glass fiber fabric (i.e., the glass fiber product) and a resin component, thereby forming a prepreg. In some embodiments, the silane coupling agent is selected from the group consisting of an amino silane coupling agent, a vinyl silane coupling agent, an acrylic silane coupling agent, and combinations thereof. In certain embodiments, based on a total weight of the glass fiber product, the silane coupling agent is in an amount ranging from 0.1 wt % to 1.2 wt %. By controlling the amount of the silane coupling agent to be not less than 0.1 wt %, good reactivity between the glass fiber product and the resin component can be achieved, thereby allowing strong bonding between the glass fiber product and the resin component. By controlling the amount of the silane coupling agent to be not greater than 1.2 wt %, the glass fiber fabric may be prevented from being excessively covered by the silane coupling agent, thereby allowing the resin component to have good impregnation property with the glass fiber product.

In the present disclosure, since the glass composition exhibits the relatively low CTE ranging from 2 ppm/° C. to 3 ppm/° C., the relatively low Dₖ ranging from 4.0 to 5.0 at 10 GHz, and the relatively low D_{f} ranging from 0.0010 to 0.0040 at 10 GHz, the glass fibers, the glass fiber yarns, the glass fiber fabric, and the glass fiber product obtained from the glass composition are also expected to have a relatively low CTE, a relatively low Dₖ and a relatively low D_{f}.

An embodiment of a prepreg according to the present disclosure includes the resin component, an inorganic filler, and the aforesaid glass fiber product.

In some embodiments, the resin component is selected from the group consisting of phenolic resin, epoxy resin, polyphenylene ether resin, bismaleimide triazine resin, fluororesin, polyimide resin, and combinations thereof.

The inorganic filler is used to improve a thermal conductivity of the prepreg so as to enable a copper clad laminated obtained from the prepreg to have a desired thermal resistance. In some embodiments, the inorganic filler is selected from the group consisting of silicon dioxide (SiO₂), aluminum oxide (Al₂O₃), and a combination thereof. In certain embodiments, the inorganic filler is silicon dioxide.

An embodiment of the copper clad laminate according to the present disclosure includes the aforesaid prepreg.

The present disclosure will be further described with reference to the following examples. However, it should be understood that the following examples are merely for illustration and should not be considered as limitation of implementing the present disclosure.

### Preparative Example 1

58.1 wt % of silicon dioxide (SiO₂), 15.3 wt % of aluminum oxide (Al₂O₃), 2.2 wt % of calcium oxide (CaO), 0.1 wt % of magnesium oxide (MgO), 2.3 wt % of zinc oxide (ZnO), 1.5 wt % of copper oxide (CuO), 19.5 wt % of boron oxide (B₂O₃), 0.5 wt % of a fluorine-containing material (i.e., a fluoride-containing mineral), and 0.5 wt % of an doping component (mainly including sodium oxide and potassium oxide) were mixed to obtain a glass composition.

### Preparative Examples 2 to 4 and Comparative Examples 1 and 2

The ingredients for preparing the glass compositions of Preparative Examples 2 to 4 and Comparative Preparative Examples 1 and 2 are similar to those of Preparative Example 1, except that the amounts of the ingredients were varied as shown in Table 1.

### Example 1

The glass composition of Preparative Example 3 was subjected to a melting treatment in a furnace to form a melted composition, and then the melted composition was subjected to a filament drawing process to form glass fibers. Then, the glass fibers were sequentially subjected to a sizing treatment, a winding treatment and a twisting treatment to form glass fiber yarns. A portion of the glass fiber yarns was used as warp yarns and another portion of the glass fiber yarns was used as weft yarns. The warp yarns were sequentially subjected to a finishing treatment and a warping treatment, and then were placed on a weaving beam. Thereafter, the warp yarns were interlaced with the weft yarns by an air-jet loom (Toyota Industries™ Corp., Model: JAT710) to obtain a glass fiber fabric.

Next, the glass fiber fabric was sequentially subjected to a desizing treatment and a fiber opening process, and then was soaked in the silane coupling agent to perform a surface treatment. After drying, a glass fiber product thus obtained has a thickness of 0.01 mm, and the silane coupling agent is in an amount of 0.62 wt % based on the total weight of the glass fiber product. The silane coupling agent was formed by mixing an amino silane coupling agent ((3-aminopropyl)trimethoxysilane) and an acetic acid solution to form a reaction solution, and then the reaction solution was subjected to a hydrolysis reaction at a pH value ranging from 3.5 to 5.5 for 30 minutes, so as to obtain the silane coupling agent. Based on a total weight of the reaction solution, (3-aminopropyl)trimethoxysilane has a concentration of 0.08 wt %.

Next, two of the glass fiber products, each of which was prepared by the above procedures, were subjected to an impregnation process using a resin solution including an inorganic filler (silicon dioxide), a resin component, and a solvent, followed by a curing process at 190° C. for 6 minutes to obtain two partially cured prepregs. The resin component in each of the prepregs is in an amount of 83.4 wt %. The resin component is epoxy (EPO) resin (commercially available from Nan Ya Plastics™ Corp, catalog no. NPEB-475K70), and the solvent is 1-methoxy-2-propanol. Based on a total weight of the resin solution, the resin component has a concentration of 60 wt %.

Next, the partially cured prepregs were stacked to form a first laminate. Two copper sheets, each having a thickness of 1 Hoz, were respectively attached to two opposite surfaces of the first laminate to form a second laminate.

Then, the second laminate was pressed by a vacuum lamination tool (Vigor machinery™ Co., Ltd., Model: V8117A) at 210° C. for 1.5 hours to obtain a copper clad laminate. The detailed parameters for forming the copper clad laminate of Example 1 and characteristics thereof are presented in Table 2.

### Examples 2 to 6

The procedures and conditions for preparing the glass fiber products, the prepregs, and the copper clad laminates of Examples 2 to 6 are similar to those of Example 1, except that detailed parameters for forming the copper clad laminates (including configurations of the glass fiber products, the silane coupling agents, and the resin components) were varied. The detailed parameters for forming the copper clad laminates of Examples 2 to 6 and characteristics thereof are presented in Table 2.

The parameters for the configurations of the glass fiber products may include (i) a diameter of each filament of the warp yarns and a diameter of each filament of the weft yarns, (ii) a number of filament of the warp yarns and a number of filament of the weft yarns, and (iii) a thread count of the warp yarns and a thread count of the weft yarns.

When the silane coupling agent is a vinyl silane coupling agent (vinyltrimethoxysilane), vinyltrimethoxysilane has a concentration of 0.14 wt % based on a total weight of a reaction solution (i.e., a mixture including vinyltrimethoxysilane and an acetic acid solution). When the silane coupling agent is an acrylic silane coupling agent (3-(methacryloyloxy)propyltrimethoxysilane), 3-(methacryloyloxy) propyltrimethoxysilane has a concentration of 0.10 wt % based on a total weight of a reaction solution (i.e., a mixture including 3-methacryloxypropyltrimethoxysilane and an acetic acid solution).

When a resin component in a resin solution is polyphenylene ether (PPO) resin (commercially available from Saudi Basic Industries™ Corp., catalog no. NORYL™ SA9000), a solvent in the resin solution is methyl ethyl ketone. The PPO resin is in an amount of 65 wt % based on a total weight of the resin solution. The curing process was performed at 180° C. for 4 minutes to obtain PPO-based partially cured prepregs. When a resin component in a resin solution is bismaleimide triazine (BT) resin (commercially available from Prior Company™ Ltd., catalog no. BT-0001), a solvent in the resin solution is methyl ethyl ketone. The BT resin is in an amount of 50 wt % based on a total weight of the resin solution. The curing process was performed at 210° C. for 6 minutes to obtain BT-based partially cured prepregs.

### Comparative Examples 1 to 6

The procedures and conditions for preparing the glass fiber products, the prepregs, and the copper clad laminates of Comparative Examples 1 to 6 were similar to those of Example 1, except that Comparative Preparative Example 2 was used to prepare the glass fiber composition, and the detailed parameters for forming the copper clad laminates (including the configurations of the glass fiber products, the silane coupling agents, and the resin components) were varied. The detailed parameters for forming the copper clad laminates of Comparative Examples 1 to 6 and characteristics thereof are presented in Table 3.

### Property Evaluations

### Evaluation of Coefficient of Thermal Expansion (CTE)

The glass composition of each of Preparative Examples 1 to 6 and Comparative Preparative Examples 1 and 2 was placed in a high-temperature furnace and heated at a temperature ranging from 1500° C. to 1600° C. for 1 hour to 4 hours, so as to obtain a glass liquid. Next, the glass liquid was poured into a graphite crucible having a diameter of 40 mm, and was then placed in a pre-heated annealing furnace at 800° C. to be cooled down to 25° C. so as to obtain a glass block. The glass block was cut and ground to obtain a sample with a size of 0.5 cm×0.5 cm×2 cm. Thereafter, the sample was subjected to a measurement of the CTE using a thermomechanical analyzer (Hitachi High-Tech™ Corp.; Model: TMA7100) with a heating rate of 10° C./min. The change in length of the sample at 50° C. and 200° C. was determined, and then the CTE of the sample was calculated.

The results for each of Preparative Examples 1 to 6 and Comparative Preparative Examples 1 and 2 are presented in Table 1.

Evaluation of Dielectric Constant (Dₖ) and Dielectric Loss Tangent (D_{f})

The glass composition of each of Preparative Examples 1 to 6 and Comparative Preparative Examples 1 and 2 was placed in a high-temperature furnace and heated at a temperature ranging from 1500° C. to 1600° C. for 1 hour to 4 hours, so as to obtain a glass liquid. Next, the glass liquid was poured into a graphite crucible having a diameter of 40 mm, and was then placed in a pre-heated annealing furnace at 800° C. to be cooled down to 25° C. so as to obtain a glass block. The glass block was ground and polished to obtain a test sample with a thickness ranging from 0.60 mm to 0.79 mm. Then, the test sample was subjected to measurements of the Dₖ and the D_{f} at 10 GHz using a vector network analyzer (Rohde & Schwarz GmbH™ & Co. KG; Model: ZNB20) in combination with a split post dielectric resonator (Waveray Technology™ Co., Ltd.). The Dₖ and the D_{f} of each of Preparative Examples 1 to 6 and Comparative Preparative Examples 1 and 2 thus obtained are presented in Table 1.

### Determination of Amount of Silane Coupling Agent

An amount of the silane coupling agent in each of the glass fiber products of Examples 1 to 6 and Comparative Examples 1 to 6 was evaluated in accordance to the procedures set forth in a test method in section 4.4.8 of an IPC-4412 (2006), “Specification for Finished Fabric Woven from E-Glass for Printed Boards.” For example, the glass fiber product of Example 1 was cut into samples, each of which had a size of 30 cm×30 cm. Next, the samples were placed on a stainless steel tray and heated in an oven (Dengyng Instrument™ Co., Ltd.; Model: DOS30) at a temperature ranging from 100° C. to 110° C. for 30 minutes. Then, the samples were removed from the oven for cooling so as to obtain dried glass fiber products. A weight (W1) of the dried glass fiber products was measured.

Subsequently, the dried glass fiber products were heated in a high temperature oven (Great Tide Instrument™ Co., Ltd.; Model: JH-01) at a temperature ranging from 620° C. to 630° C. for 30 minutes. Thereafter, the dried glass fiber products were removed from the high temperature oven for cooling so as to obtain heat-treated glass fiber products. A weight (W2) of the heat-treated glass fiber products was measured. The amount of the silane coupling agent was calculated according to a formula: (W1−W2)/W1×100%. Amounts of the silane coupling agent of the glass fiber products of Examples 2 to 6 and Comparative Examples 1 to 6 were also measured by the aforesaid procedures. The results are presented in Tables 2 and 3.

### Determination of Amount of Resin Component

An amount of the resin component in one of the prepregs of each of Examples 1 to 6 and Comparative Examples 1 to 6 was determined in accordance to the procedures set forth in section 2.3.16.1 of an IPC-TM-650 (1994), “Resin Content of Prepreg, by Treated Weight.” For example, a weight (X1) of the glass fiber product of Example 1, and a weight (X2) of a corresponding one of the prepregs of Example 1 made from the glass fiber product were measured. The amount of the resin component of the corresponding one of the prepregs of Examples 1 was calculated according to a formula: (X2−X1)/X2×100%. An amount of the resin component in each of the prepregs of Examples 2 to 6 and Comparative Examples 1 to 6 was also measured by the aforesaid procedures. The results are presented in Tables 2 and 3.

### Evaluation of Dimensional Stability of Copper Clad Laminate

A dimensional stability of the copper clad laminate in each of Examples 1 to 6 and Comparative Examples 1 to 6 was evaluated in accordance to the procedures set forth in a standard test method in section 2.4.39 of the IPC-TM-650 (1994), “Dimensional Stability, Glass Reinforced Thin Laminates.” For example, the copper clad laminate of Examples 1 was formed with four holes on four corresponding positions by a drilling machine. Then, prior to performing an etching treatment, distances in a warp direction and distances in a weft direction of the holes were measured using a coordinate measuring machine (Optek Technology™, Inc; Model: 713VSA). Then, the copper clad laminate of Example 1 was subjected to the etching treatment so as to obtain a testing sample. The testing sample was hung vertically in an oven and heated at a temperature ranging from 145° C. to 155° C. for 2 hours, and was then immediately cooled down in a drying box for 1 hour. Thereafter, the testing sample was removed from the drying box, and the distances among the holes in the warp direction and the distances among the holes in the weft direction were measured. After the etching and heating treatments, in the copper clad laminate of Example 1, each of a dimensional variation in the warp direction and a dimensional variation in the weft direction was calculated in accordance to a dimensional stability formula described in the standard test method in section 2.4.39 of the IPC-TM-650 (1994), “Dimensional Stability, Glass Reinforced Thin Laminates”. Dimensional stabilities of the copper clad laminates of Examples 2 to 6 and Comparative Examples 1 to 6 were also evaluated by the aforesaid procedures. The results are presented in Tables 2 and 3.

TABLE 1

| | | | | | Comparative | |
|---|---|---|---|---|---|---|
| | Preparative Example | | | | Preparative Example | |
| | 1 | 2 | 3 | 4 | 1 | 2 |
| SiO₂ (wt %) | 58.1 | 59.3 | 55.4 | 55.3 | 55.9 | 54.5 |
| Al₂O₃ (wt %) | 15.3 | 19.7 | 18.2 | 19.2 | 18.6 | 14.2 |
| CaO (wt %) | 2.2 | 1.9 | 2.3 | 0.2 | 3.5 | 18.7 |
| MgO (wt %) | 0.1 | 1.5 | 1.9 | 3.2 | 7.9 | 4.9 |
| ZnO (wt %) | 2.3 | 0 | 6.5 | 5.5 | 1.8 | 0 |
| CuO (wt %) | 1.5 | 0.5 | 0.2 | 1.5 | 0.8 | 0 |
| B₂O₃ (wt %) | 19.5 | 16.1 | 14.5 | 13.5 | 10.0 | 6.1 |
| Fluorine-containing | 0.5 | 0.5 | 0.5 | 0.5 | 0.5 | 0.2 |
| material (wt %) | | | | | | |
| Doping component | 0.5 | 0.5 | 0.5 | 1.1 | 1.0 | 1.4 |
| (wt %) | | | | | | |
| CTE (ppm/° C.) | 2.99 | 2.80 | 2.68 | 2.62 | 3.28 | 5.60 |
| Dₖ (at 10 GHz) | 4.56 | 4.82 | 4.89 | 4.95 | 5.04 | 6.74 |
| D_{f} (at 10 GHZ) | 0.0017 | 0.0028 | 0.0032 | 0.0040 | 0.0042 | 0.0065 |
| 1000 × (D_{f}//Dₖ) × | 3.3 | 4.6 | 4.7 | 5.5 | 8.8 | 30.2 |
| (CTE)² | | | | | | |

TABLE 2

| | | Example | | | | | |
|---|---|---|---|---|---|---|---|
| | | 1 | 2 | 3 | 4 | 5 | 6 |
| Glass- | Material of silane | Amino¹ | Vinyl² | Amino¹ | Acryl³ | Amino¹ | Amino¹ |
| fiber | coupling agent | | | | | | |
| product | Amount of silane | 0.62 | 1.1 | 0.54 | 0.90 | 0.43 | 0.37 |
| | coupling agent | | | | | | |
| | (wt %) | | | | | | |
| | Basis weight (g/m²) | 9.7 | 18.1 | 21.2 | 27.4 | 43.5 | 96 |
| | Thickness (mm) | 0.01 | 0.02 | 0.024 | 0.03 | 0.044 | 0.084 |
| | Diameter of single | 4 | 4 | 4.5 | 5 | 5 | 7 |
| | filament in each | | | | | | |
| | warp yarn (μm) | | | | | | |
| | Number of | 40 | 100 | 100 | 100 | 200 | 200 |
| | filaments in each | | | | | | |
| | warp yarn | | | | | | |
| | Thread count of | 95 | 75 | 70 | 66 | 54 | 60 |
| | each warp yarn | | | | | | |
| | Diameter of single | 4 | 4 | 4.5 | 5 | 5 | 7 |
| | filament in each | | | | | | |
| | weft yarn (μm) | | | | | | |
| | Number of | 40 | 100 | 100 | 100 | 200 | 200 |
| | filaments in each | | | | | | |
| | weft yarn | | | | | | |
| | Thread count of | 95 | 75 | 73 | 68 | 54 | 57 |
| | each weft yarn | | | | | | |
| Prepreg | Material of resin | EPO | PPO | EPO | PPO | EPO | BT |
| | component | | | | | | |
| | Amount of resin | 83.4 | 77.1 | 72.7 | 70.5 | 67.9 | 63.2 |
| | component (wt %) | | | | | | |
| | Inorganic filler | SiO₂ | SiO₂ | SiO₂ | SiO₂ | SiO₂ | SiO₂ |
| Copper | Dimensional | −697 | −482 | −-401 | −335 | −301 | −201 |
| clad | variation in warp | | | | | | |
| laminate | direction (ppm) | | | | | | |
| | Dimensional | −903 | −608 | −496 | −424 | −354 | −228 |
| | variation in weft | | | | | | |
| | direction (ppm) | | | | | | |
| | Ratio of | 1.30 | 1.26 | 1.24 | 1.27 | 1.18 | 1.13 |
| | dimensional | | | | | | |
| | variation in weft | | | | | | |
| | direction to | | | | | | |
| | dimensional | | | | | | |
| | variation in warp | | | | | | |
| | direction | | | | | | |

¹(3-Aminopropyl)trimethoxysilane
²Vinyltrimethoxysilane
³3-(Methacryloyloxy)propyltrimethoxysilane

TABLE 3

| | | Comparative Example | | | | | |
|---|---|---|---|---|---|---|---|
| | | 1 | 2 | 3 | 4 | 5 | 6 |
| Glass- | Material of silane | Amino¹ | Vinyl² | Amino¹ | Acryl³ | Amino¹ | Amino¹ |
| fiber | coupling agent | | | | | | |
| product | Amount of silane | 0.22 | 0.71 | 0.14 | 0.50 | 0.13 | 0.07 |
| | coupling agent | | | | | | |
| | (wt %) | | | | | | |
| | Basis weight (g/m²) | 10 | 19.5 | 23 | 29.5 | 48 | 103.5 |
| | Thickness (mm) | 0.012 | 0.025 | 0.028 | 0.032 | 0.051 | 0.088 |
| | Diameter of | 4 | 4 | 4.5 | 5 | 5 | 7 |
| | single filament in | | | | | | |
| | each warp yarn (μm) | | | | | | |
| | Number of filaments | 40 | 100 | 100 | 100 | 200 | 200 |
| | in each warp yarn | | | | | | |
| | Thread count of | 95 | 75 | 70 | 66 | 54 | 60 |
| | each warp yarn | | | | | | |
| | Diameter of single | 4 | 4 | 4.5 | 5 | 5 | 7 |
| | filament in each | | | | | | |
| | weft yarn (μm) | | | | | | |
| | Number of | 40 | 100 | 100 | 100 | 200 | 200 |
| | filaments in each | | | | | | |
| | weft yarn | | | | | | |
| | Thread count of | 95 | 75 | 73 | 68 | 54 | 57 |
| | each weft yarn | | | | | | |
| Prepreg | Material of resin | EPO | PPO | EPO | PPO | EPO | BT |
| | component | | | | | | |
| | Amount of resin | 81.1 | 74.5 | 71.8 | 68.6 | 65.9 | 61.2 |
| | component (wt %) | | | | | | |
| | Inorganic filler | SiO₂ | SiO₂ | SiO₂ | SiO₂ | SiO₂ | SiO₂ |
| Copper | Dimensional | −1003 | −789 | −714 | −561 | −06 | −375 |
| clad | variation in warp | | | | | | |
| laminate | direction (ppm) | | | | | | |
| | Dimensional | −1674 | −1363 | −1227 | −825 | −698 | −502 |
| | variation in weft | | | | | | |
| | direction (ppm) | | | | | | |
| | Ratio of | 1.67 | 1.73 | 1.72 | 1.47 | 1.38 | 1.34 |
| | dimensional | | | | | | |
| | variation in weft | | | | | | |
| | direction to | | | | | | |
| | dimensional | | | | | | |
| | variation in warp | | | | | | |
| | direction | | | | | | |

¹(3-Aminopropyl)trimethoxysilane
²Vinyltrimethoxysilane
³3-(Methacryloyloxy)propyltrimethoxysilane

Referring to Table 1 and Table 3, the glass composition of Preparative Example 3, which is used for preparing the glass fiber products of Examples 1 to 6, exhibits a low CTE of 2.68 ppm/° C. In contrast, the glass composition of Comparative Preparative Example 2, which is used for preparing the glass fiber products of Comparative Examples 1 to 6, exhibits a CTE of up to 5.6 ppm/° C. Thus, when the configurations of the glass fiber fabrics are the same, compared to the copper clad laminates of Comparative Examples 1 to 6, the copper clad laminates of Examples 1 to 6 exhibit lower dimensional variations and show good dimensional stabilities. Therefore, defects (e.g., displacement of inner circuits (or patterns), distortion of holes, etc.) caused by the dimensional variation during the subsequent production of printed circuit boards may be avoided. In addition, the glass composition of Preparative Example 3, which is used for preparing the glass fiber products of Examples 1 to 6, at 10 GHz, has a Dₖ not greater than 5 and a D_{f} not greater than 0.0040, and satisfies the equation of 1.0≤1000×(D_{f}/Dₖ)×(CTE)²≤7.2. As a result, the glass fiber products of Examples 1 to 6 are expected to not only have a low CTE but also exhibit a low Dₖ and a low D_{f}, thereby meeting requirements for integrated circuit substrates in next generation massive 5G wireless transmission, big data fast computing, and high-end servers.

In contrast, the glass composition of Comparative Preparative Example 2, which is used for preparing the glass fiber products of Comparative Examples 1 to 6, at 10 GHZ, exhibits a Dₖ of 6.74 and a D_{f} of 0.0065. A value obtained from 1000×(D_{f}/Dₖ)×(CTE)² is 30.2, and thus the glass composition of Comparative Preparative Example 2 does not satisfy the equation of 1.0≤1000×(D_{f}/Dₖ)×(CTE)²≤7.2. Therefore, the glass fiber products of Comparative Examples 1 to 6 may not simultaneously have a low CTE, a low Dₖ, and a low D_{f}.

In summary, through the design of the glass fiber fabric, the glass fiber product according to the present disclosure, which is obtained from the glass fiber fabric, may exhibit a low CTE, a low Dₖ and a low D_{f}. Such glass fiber product may be used for preparing the integrated circuit substrates in the next generation massive 5G wireless transmission and the big data fast computing, and for preparing circuit boards in the high-end servers that require a superior dimensional stability and that are suitable for fast computing and signal transmission, and thus can indeed achieve an object of the present disclosure. In addition, the prepregs and the copper clad laminate having the same include the aforesaid glass fiber product. Thus, the prepregs and the copper clad laminate having the same of the present disclosure are also expected to have a low CTE, a low Dₖ, and a low D_{f}, and thus are suitable for preparing the integrated circuit substrates in the next generation massive 5G wireless transmission, the big data fast computing, and the high-end servers.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A glass fiber product, comprising:
a glass fiber fabric having glass fiber yarns woven together, each of said glass fiber yarns being made of glass fibers, and including a glass composition, said glass composition having a coefficient of thermal expansion (CTE) ranging from 2 ppm/° C. to 3 ppm/° C., a dielectric constant (Dₖ) ranging from 4.0 to 5.0 at 10 GHz, and a dielectric loss tangent (D_{f}) ranging from 0.0010 to 0.0040 at 10 GHZ, the CTE, the Dₖ, and the D_{f} of said glass composition satisfying an equation of 1.0≤1000×(D_{f}/Dₖ)×(CTE)²≤7.2; and
a silane coupling agent.

2. The glass fiber product as claimed in claim 1, wherein said glass composition includes silicon dioxide, aluminum oxide, calcium oxide, magnesium oxide, copper oxide, and boron oxide.

3. The glass fiber product as claimed in claim 2, wherein silicon dioxide is in an amount ranging from 50 wt % to 60 wt % based on a total weight of said glass composition.

4. The glass fiber product as claimed in claim 2, wherein aluminum oxide is in an amount ranging from 15 wt % to 22 wt % based on a total weight of said glass composition.

5. The glass fiber product as claimed in claim 2, wherein calcium oxide is in an amount greater than 0 wt % and less than 6 wt % based on a total weight of said glass composition.

6. The glass fiber product as claimed in claim 2, wherein magnesium oxide is in an amount greater than 0 wt % and less than 7 wt % based on a total weight of said glass composition.

7. The glass fiber product as claimed in claim 2, wherein copper oxide is in an amount greater than 0 wt % and less than 2 wt % based on a total weight of said glass composition.

8. The glass fiber product as claimed in claim 2, wherein boron oxide is in an amount greater than 10 wt % and less than 20 wt % based on a total weight of said glass composition.

9. The glass fiber product as claimed in claim 2, wherein said glass composition further includes zinc oxide.

10. The glass fiber product as claimed in claim 9, wherein zinc oxide is in an amount greater than 0 wt % and less than 8 wt % based on a total weight of said glass composition.

11. The glass fiber product as claimed in claim 2, wherein said glass composition further includes a fluorine-containing material.

12. The glass fiber product as claimed in claim 11, wherein the fluorine-containing material is in an amount greater than 0 wt % and not greater than 1 wt % based on a total weight of said glass composition.

13. The glass fiber product as claimed in claim 2, wherein said glass composition further includes a doping component, and said doping component is selected from the group consisting of sodium oxide, potassium oxide, iron oxide, and combinations thereof.

14. The glass fiber product as claimed in claim 1, wherein said silane coupling agent is selected from the group consisting of an amino silane coupling agent, a vinyl silane coupling agent, an acrylic silane coupling agent, and combinations thereof.

15. The glass fiber product as claimed in claim 1, wherein, based on a total weight of said glass fiber product, said silane coupling agent is in an amount ranging from 0.1 wt % to 1.2 wt %.

16. A prepreg, comprising:
a resin component;
an inorganic filler; and
said glass fiber product as claimed in claim 1.

17. The prepreg as claimed in claim 16, wherein said resin component is selected from the group consisting of phenolic resin, epoxy resin, polyphenylene ether resin, bismaleimide triazine resin, fluororesin, polyimide resin, and combinations thereof.

18. A copper clad laminate, comprising said prepreg as claimed in claim 16.
